(19) United States
(12) Patent Application Publication
(10) Pub. No.: US 2023/0342206 A1
(43) Pub. Date: Oct. 26, 2023

(54) HARDWARE-BASED GENERATION OF UNCOMPRESSED DATA BLOCKS

(71) Applicant: Intel Corporation, Santa Clara, CA (US)

(72) Inventors: Laurent Coquerel, Limerick (IE); Fei Wang, Shannon (IE); Smita Kumar, Chandler, AZ (US); Phani Krishna Sagiraju, Bangalore (IN); John J. Browne, Limerick (IE)

(21) Appl. No.: 18/214,830

(22) Filed: Jun. 27, 2023

(30) Foreign Application Priority Data
Dec. 13, 2022 (IN) 202241071945

(51) Int. Cl. G06F 9/50; H03M 7/30

(52) U.S. Cl. CPC G06F 9/5027; H03M 7/30

(57) ABSTRACT

An accelerator or system including an accelerator can include an input interface to receive input data to be compressed and user application parameters for invocation of compression. The accelerator can include circuitry to identify a compression algorithm from configuration data provided with the input data. The user application parameters may not include parameters specifying entropy thresholds for compression of the input data. The circuitry can generate headers specific to the compression algorithm. The circuitry can generate uncompressed data blocks comprising blocks of the input data and corresponding headers. The circuitry can determine whether to provide the uncompressed data blocks or compressed data blocks based at least in part on entropy of the input data. Other methods, systems, and apparatuses are described.

This application claims the benefit of priority to India Provisional Patent Application No. 202241071945, filed on Dec. 13, 2022, which is incorporated herein by reference in its entirety.

### BACKGROUND

Modern computing devices can receive data communications over data networks. Data compression considerations have become increasingly important due to the large amounts of data being received, and due to bandwidth constraints and latency associated with moving large amounts of data across a network. Data compression may be used to reduce network bandwidth requirements and/or storage requirements for cloud computing applications. Such applications in networked computing devices often require lossless compression algorithms to perform the compression and decompression of data streams. However, if the data becomes corrupted, it may become impossible to decompress and use the data.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 is a block diagram of computing device in which compression error recovery is implemented in accordance with various embodiments.

FIG. 2 is a simplified block diagram of an accelerator apparatus that can be incorporated within a compute device in accordance with some embodiments.

FIG. 3 is a block diagram illustrating further details of the circuitry for generating uncompressed data blocks in accordance with some embodiments.

FIG. 4A illustrates an uncompressed data block format for a DEFLATE compression format in accordance with some embodiments.

FIG. 4B illustrates an uncompressed data block format for a LZ4 compression format in accordance with some embodiments.

FIG. 4C illustrates an uncompressed data block format for a ZSTD compression format in accordance with some embodiments.

FIG. 5 illustrates a method for generated uncompressed data blocks in accordance with some embodiments.

### DETAILED DESCRIPTION

Computer systems in use today perform data compression to make more efficient use of finite storage space and to meet other requirements such as latency and bandwidth requirements. Compression can be used in multiple contexts, including with accelerators and other offload engines. Some accelerators that can be employ compression methods and technologies according to example embodiments can include Intel® QuickAssist Technology (QAT), IAX or Intel® Data Streaming Accelerator (DSA). Other accelerators can include Panther® series accelerators available from MaxLinear of Carlsbad, California. Still further accelerators can include products of the BlueField® family of products available from NVIDIA® of Santa Clara, California. Still further accelerators can include accelerators associated with a Zipline family of products available from Broadcom Inc. of San Jose, California. Still further accelerators can include accelerators associated with the Elastic Compute Cloud services and Amazon Web Services AWS) Nitro available through Amazon of Seattle, Washington. Still further accelerators can include Cryptographic Co-Processor (CCP) or other accelerators available from Advanced Micro Devices, Inc. (AMD®) of Sunnyvale, California. Still further accelerators can include an ARM®-based accelerators available ARM Holdings, Ltd., or a customer thereof, or their licensees or adopters, such as Security Algorithm Accelerators and CryptoCell-300 Family accelerators. Further accelerators can include AI Cloud Accelerator (QAIC) available from Qualcomm® Technologies, Inc.

A compressed data set can comprise a series of blocks corresponding to successive blocks of input data. Each block can be compressed using various algorithms and the uncompressed data can be recovered during a recovery process. However, errors can occur during compression and recovery, and systems can provide error recovery responsive to these errors.

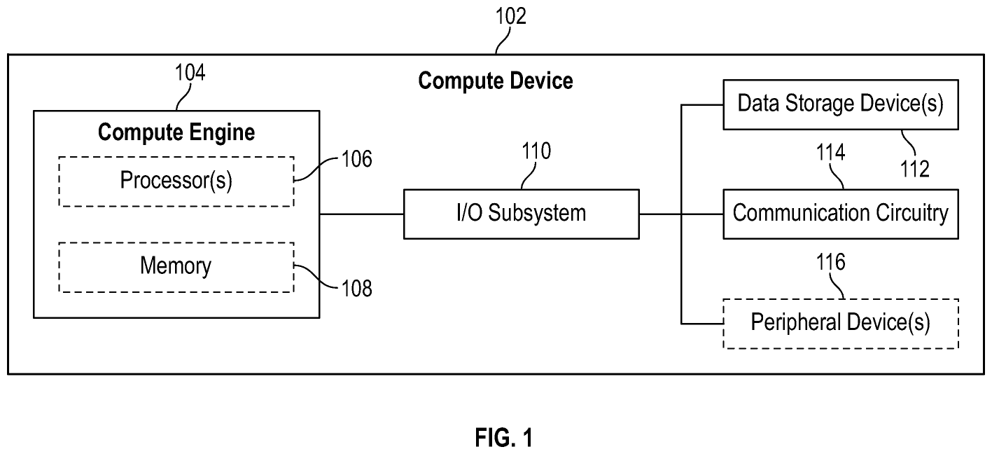

FIG. 1 is a block diagram of compute device 102 in which compression error recovery is implemented in accordance with various embodiments. The compute device 102 may be embodied as any type of computation or computer device capable of performing the functions described herein, including, without limitation, a computer, a server (e.g., stand-alone, rack-mounted, blade, etc.), a sled (e.g., a computing sled, an accelerator sled, a storage sled, a memory sled, etc.), an enhanced or smart NIC (e.g., a host fabric interface (HFI)), a network appliance (e.g., physical or virtual), a web appliance, a distributed computing system, a processor-based system, and/or a multiprocessor system. It should be appreciated that the functions described herein may be performed on any bump-in-the-wire applications with one-to-one ingress/egress ports (e.g., a gateway, an Internet Protocol Security (IPSec) appliance, etc.), but not all packet processing workloads (e.g., routers or switches that distribute traffic to multiple ports).

The compute device 102 includes a compute engine 104, an I/O subsystem 110, one or more data storage devices 112, communication circuitry 114, and, in some embodiments, one or more peripheral devices 116. It should be appreciated that the compute device 102 may include other or additional components, such as those commonly found in a typical computing device (e.g., various power and cooling devices, graphics processing unit(s), and/or other components), in other embodiments, which are not shown here to preserve clarity of the description. Additionally, in some embodiments, one or more of the illustrative components may be incorporated in, or otherwise form a portion of, another component.

The compute engine 104 can include any number of device/s for performing compute functions described herein. For example, the compute engine 104 can comprise a single device such as an integrated circuit, an embedded system, a field-programmable-array (FPGA), a system-on-a-chip (SoC), an application specific integrated circuit (ASIC), on-die implementations, chiplet implementations, as a discrete part, as an add-on card, reconfigurable hardware or hardware circuitry, or other specialized hardware to facilitate performance of the functions described herein. Additionally, in some embodiments, the compute engine 104 may include one or more processors 106 (e.g., one or more central processing units).

As mentioned earlier herein, the compute device 102 can perform compression operations on input data, or on an input stream of data. Compression can occur particularly in Big Data systems, in storage systems before writing data to disk, before sending data onto a network for bandwidth performance improvements, and at other points in a system. If errors exist in the compressed bits, data can become unusable by downstream devices. To verify the compression operation was performed without error, the compute device 102 can perform a compression validation operation on the compressed data. Depending on results of this verification, or other criteria, different recovery techniques described below can be implemented.

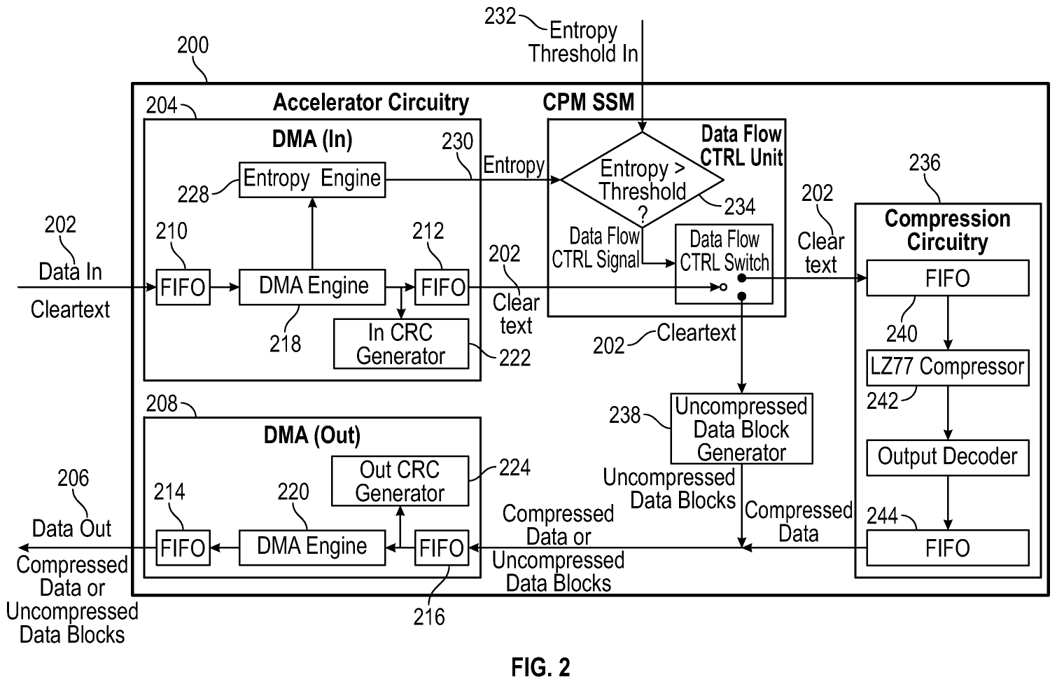

FIG. 2 is a simplified block diagram of an accelerator apparatus 200 that can be incorporated within a compute device in accordance with some embodiments FIG. 2 illustrates how compression, compression validation, and error recovery can be performed in accordance with some embodiments. Any of the components shown in FIG. 2 can be implemented in hardware, firmware, software, or a combination thereof. In various example embodiments, therefore, the components shown in FIG. 2 can include processing circuitry, memory, an application specific integrated circuit (ASIC), a programmable circuit such as a field-programmable gate array (FPGA), and/or other components of the compute device 102.

As seen in FIG. 2, data (provided in, for example cleartext or any other format) can be input at 202 by, for example direct memory access (DMA) circuitry 204 from a source. The data input at 202 (as well as the data output at 206 as discussed below) will have been previously allocated by an application requesting compression. For example, an application programming interface (API) call may be made providing the input at 202 and the API call includes user application data (e.g., user application parameters or other data). Data 206, whether compressed or uncompressed, can be output through, for example, DMA circuitry 208. Either DMA circuitry 204, 208 can include buffers 210, 212, 214, 216 (e.g., first-in-first-out (FIFO) buffers) as inputs or outputs to DMA engines 218, 220. DMA engines 218, 220 allow hardware to access main system memory (e.g., memory 108 (FIG. 1)) independently of processors of the compute device 102 (e.g., a central processing unit (CPU) of the compute device 102). Any of the data or data buffers described herein can be combined, aggregated, and/or otherwise form portions of a single or multiple data sets, including duplicative copies, in some embodiments. Cyclic redundancy check (CRC) circuitry 222, 224 can be provided at outputs of the DMA engine 218 or as inputs to the DMA engine 220 for additional error checking of input and output data 202, 206.

Entropy circuitry 228 can determine if entropy of the input data 202 is high by providing a measure of entropy at line 230. This entropy indication therefore will not be provided by the API call or associated user application data or user application parameters described above, and other data indicating which compression algorithm is to be used will not be provided by the API call described above. In the context compression according to example embodiments, entropy is the amount of randomness in a given payload. For example, or the amount of information present in the data expressed in units of bits. To preserve data accurately, lossless compression is used to reduce the number of bits used to represent the data. Entropy can be expressed as the limit to how few bits are needed to represent the data. Depending on whether entropy represented at line 230 is above a threshold 232 (as determined at decision 234), data (e.g., cleartext received at input 202) can be switched to either compression circuitry 236 or hardware circuitry 238 for generating uncompressed data blocks, as described later herein.

Compression circuitry 236, which may be embodied as hardware, firmware, software, virtualized hardware, emulated architecture, and/or a combination thereof as discussed above, can perform a lossless compression (e.g., using a lossless compression algorithm, such as DEFLATE) on uncompressed input data to generate lossless compressed output data. For example, in some embodiments, the compression circuitry 236 may include a compression accelerator usable to offload the lossless compression of an input data stream. In some embodiments, the input data stream and/or data related thereto (e.g., length/size, address in memory, etc.) may be stored in the buffer 240.

Compressor 242 implements compression. In an illustrative embodiment, compressor 242 may use a lossless compression format based on Lempel-Ziv based algorithms, such as the LZ77 compression algorithm. In such embodiments, data compressed using LZ77-based algorithms typically include a stream of symbols (or “tokens”). Each symbol may include literal data that is to be copied to the output or a reference to repeat data that has already been decompressed.

Further regarding compression, the compressor 242 may execute an LZ77-based compression algorithm (e.g., DEFLATE) to match repeated strings of bytes in the data block. It should be appreciated that the DEFLATE algorithm uses LZ77 compression in combination with Huffman encoding to generate compressed output in the form of a stream of output symbols. The output symbols may include literal symbols, length symbols, or distance symbols, and each particular symbol may occur in the data block with a particular frequency. The symbol list thus may include a list of all symbols that occur with non-zero frequency in the data block, and the symbol list may include length/literal symbols or distance symbols. While illustratively described as using LZ77 compression in combination with Huffman encoding to generate compressed output, other compression algorithms may be used, such as may be dependent on the size of the history window associated with the compression algorithm. For example, the DEFLATE algorithm uses a 32-kilobyte history window when searching for matching data, while other, newer compression algorithms may use larger history windows, such as the Brotli and ZStandard compression algorithms that use history windows up to the megabyte range.

Uncompressed data blocks can be generated to be used in the place of compressed data if errors are detected in the input data or compression. Furthermore, if input data is uncompressible, uncompressed data blocks can be provided according to various methodologies. An uncompressed data block can comprise uncompressed data and a header associated with a compression algorithm that has been specified in configuration data received according to example aspects.

Some available earlier systems for verifying and validating compression (and generating uncompressed data blocks) were implemented with firmware or other non-hardware-based algorithms, which could lead to memory storage issues because of the code store needed to store this firmware. Uncompressed blocks were only generated dynamically upon detection of errors in input data 202 or in compression. Latency would also be increased because uncompressed data blocks would be generated only after verifying and discovering errors. Depending on configurations and user preferences, uncompressed data blocks could be produced very frequently, further adding to latency. Finally, when new compression algorithms were used, or a developer decided to use additional compression algorithms, firmware would need to be developed and/or updated to support verification of the new/additional compression algorithms.

Example embodiments of the present disclosure address these and other concerns by performing verification and block generation within hardware circuitry. Uncompressed blocks are generated in example embodiments to include a block header and uncompressed data (e.g., cleartext, or data 202, for example). Comparison features can be provided in Auto Select Best (ASB) and Compress and Verify and Recover (CnVnR) features, within the same or similar hardware circuitry in some embodiments. Uncompressed blocks can be generated during ASB and/or CnVnR. When uncompressed blocks are generated during ASB, a best compression ratio can be achieved. When uncompressed blocks are generated during CnVnR, systems can recover from a failed compression service.

Hardware circuitry 238 can validate whether the compression of the input data was successful (i.e., no bit errors were found in the compressed data resulting from the compression operation as performed by the compression circuitry 236). Hardware circuitry 238 can detect whether an error occurred during the compression of the input data by performing a compression error check on the compressed data. The error check can include retrieving the initial uncompressed data of the input stream that was compressed (e.g., via the compression circuitry 236), retrieve or otherwise receive the compressed data (e.g., from a storage buffer 244, from the compression circuitry 236, etc.), decompress the compressed data, and compare the decompressed data to the initial uncompressed data of the input stream (e.g., from the data 202, or buffers 210, 212).

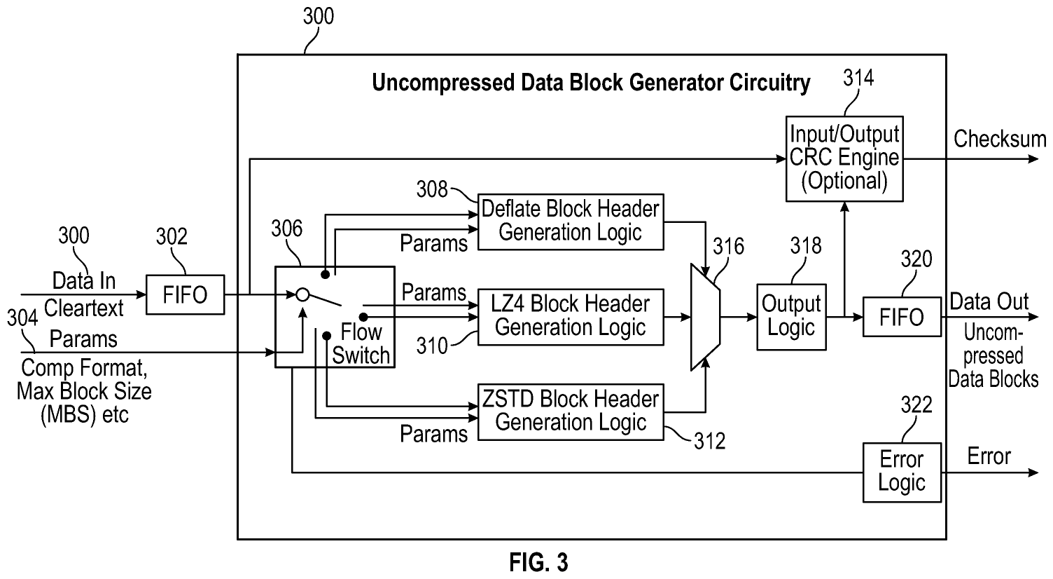

FIG. 3 is a block diagram illustrating further details of the hardware circuitry 238 for generating uncompressed data blocks in accordance with some embodiments. At input 300, data can be received by, e.g., a DMA engine 218 (FIG. 2) as cleartext to the stored block generator and move uncompressed data blocks to DRAM. Therefore, the hardware circuitry 238 does not need to include a separate dedicated DMA engine. The data 300 can be stored in buffer 302.

Other input parameters 304 can provide information regarding the compression format (e.g., identification of the compression format or compression format algorithm) that is to be used (or was used) in compressing cleartext input data in compression circuitry 236. Input parameters 304 can further include information regarding maximum block size (MBS) and other parameters. In the example of the LZ4 compression algorithm, some example MBS values include 64 kilobytes, 256 kilobytes, 1 megabyte, 4 megabytes, etc.

The hardware circuitry 238 can include a hardware switch 306, which switches flow to generation logic depending on values of the parameters 304. Uncompressed data block formats have been defined for several different compression algorithms. Accordingly, hardware circuitry 238 can generate uncompressed data blocks comprising uncompressed data and data headers, wherein the hardware circuitry 238 provides data headers depending on parameters provided at parameters 304. For example, the hardware circuitry 238 can include DEFLATE block header generation logic 308 to provide headers on blocks of uncompressed cleartext data if the parameters 304 indicate that a DEFLATE header should be used. In examples, presence of the DEFLATE header can indicate compression compatible with the DEFLATE compression algorithm as specified by the Internet Engineering Task Force (IETF) in RFC 1951. DEFLATE compression utilizes a combination of an LZ77 compression algorithm to find repeated strings in an input data buffer, and Huffman coding to code the data elements output by the LZ77 compression algorithm.

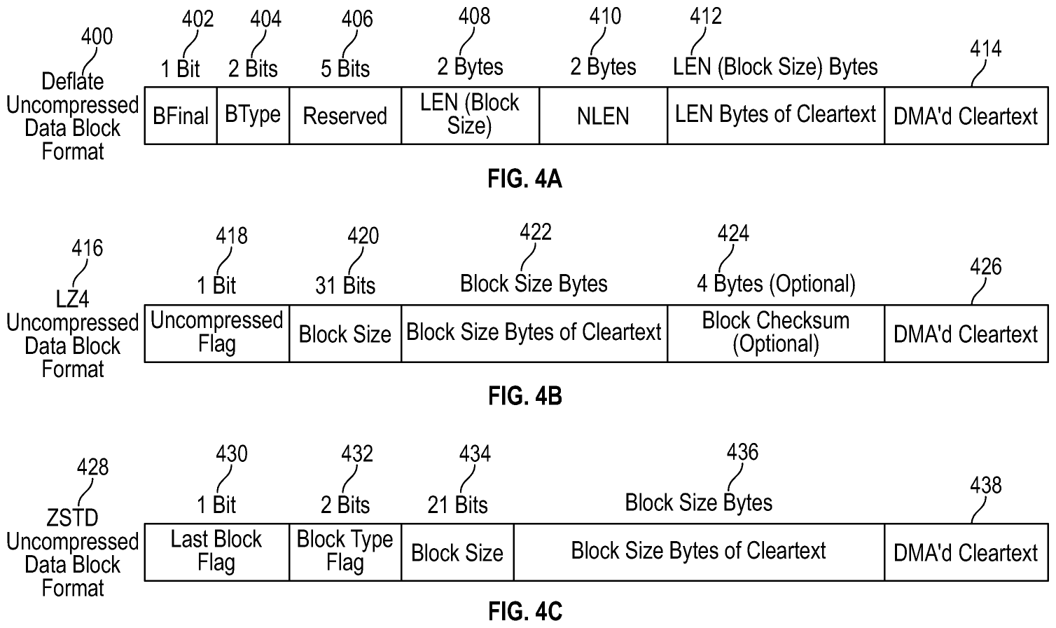

Similarly, the hardware circuitry 238 can use LZ4 block header generation logic 310 to provide LZ4 headers on blocks of uncompressed cleartext data if the parameters 304 indicate that LZ4 headers should be used. The hardware circuitry 238 can use ZSTD block header generation logic 312 to provide ZSTD headers on blocks of uncompressed cleartext data if the parameters 304 indicate that ZSTD headers should be used. While three examples are shown, other headers can be provided if other compression formats or algorithms are used. Compression and decompression types can also be determined based on the Multipurpose Internet Mail Extension (MIME) data type of the data to be compressed/decompressed. FIG. 4A, FIG. 4B and FIG. 4C illustrate uncompressed data block formats for various algorithms and compression formats. While specific options are shown, it will be understood that other compression formats and algorithms can also be supported. Accordingly, FIG. 4A, FIG. 4B, and FIG. 4C should be considered to be examples only, and not meant to limit embodiments.

FIG. 4A illustrates an uncompressed data block format 400 for a DEFLATE compression format in accordance with some embodiments. Field 402 indicates whether the corresponding block is a last block of a data set. Field 404 indicates how data is compressed. Examples values can include: “00” if no compression is used; “01” if data is compressed with fixed Huffman codes; “10” if data is compressed with dynamic Huffman codes; and “11” is reserved for errors. Field 406 is reserved. Field 408 indicates the number of data bytes in the corresponding block. Field 410 is a one's complement of field 408. Field 412 indicates the number of bytes of cleartext (e.g., the data 300 (FIG. 3)). Fields 402, 404, 406, 408, 410, and 412 comprise a header hat the hardware circuitry 238 can add to DMA'd cleartext 414 (e.g., input data 300 (FIG. 3)).

FIG. 4B illustrates an uncompressed data block format 416 for a LZ4 compression format in accordance with some embodiments. Field 418 indicates whether the corresponding data is uncompressed. In examples, field 418 will typically be set at least because the corresponding data is typically uncompressed. If the field is set (1), the block is uncompressed; otherwise, the block is LZ4-compressed, using the LZ4 block format specification. Field 420 indicates the size, in bytes, of the data section (e.g., field 422). The size does not include the block checksum if present. Field 422 includes the data of the block. Field 424 includes a 4-bytes checksum value, in little endian format, calculated by using the xxHash-32 algorithm on the raw (undecoded) data block 422, and a seed of zero. Field 424 can be used to detect data corruption (storage or transmission errors) before decoding. Fields 418, 420 422, and 424 comprise a header hat the hardware circuitry 238 can add to DMA'd cleartext 426 (e.g., input data 300 (FIG. 3)).

FIG. 4C illustrates an uncompressed data block format 428 for a ZSTD compression format in accordance with some embodiments. Field 430 indicates whether the corresponding block is a last block of a data set. Field 432 indicates a block type, wherein values can include: “0” for uncompressed blocks; “1” for a single byte repeated a number of times up to the block size; “2” for a ZStandard compressed block; and “3” to indicate corrupted data or other reserved, undefined value. Field 434 indicates block size and is limited by MSB for the compression type. Field 436 includes the data of the block. Fields 430, 432 434, and 436 comprise a header hat the hardware circuitry 238 can add to DMA'd cleartext 438 (e.g., input data 300 (FIG. 3)).

As can be appreciated upon examination of FIG. 4A, FIG. 4B and FIG. 4C, each example requires information regarding the block size to generate the corresponding headers. This can be calculated based on the cleartext data length (determined from input data 300) and the compression format-specific maximum block size. Accordingly, information regarding the compression format parameters specific to that compression format (e.g., MSB) shall be included as input parameters 302 (FIG. 3) to the hardware circuitry 238. Accordingly, as all information needed by the hardware circuitry 238 is provided as inputs, no firmware is needed to perform the operations of the hardware circuitry 238. Rather, all operations can occur using hardware without the need to invoke firmware.

Referring again to FIG. 3, an optional checksum engine 314 can compute both input/output checksums (the input checksum of cleartext and the output checksum of uncompressed data blocks) of format specific content checksum and optional block checksum (e.g., LZ4 format). The combination of these modules will remove any interaction with firmware.

Block 316 redirects the block header (wherein the block header was generated in one of blocks 308, 310, 312) to output logic 318. The output logic 318 can combine the redirected block header and the uncompressed data respecting the stored block format as defined in the specification for each compression algorithm. Uncompressed data blocks are stored in buffer 320 before being output.

Error logic 322 can determine whether a compression error has been detected. For example, if a compression error has been detected during parameter check operations (e.g., within block 306), or in stored block generation logic (e.g., in blocks 308, 310, 312, 316 and 318), error logic 322 can report the error to software and the error logic 322 can prevent the stored block generation from being output.

Threshold 232 can be used to determine whether the input cleartext data is sent to the stored block generator 238 or to compression circuitry 236. For example, if the entropy of cleartext data is below an entropy threshold as determined at decision 234, the input cleartext data is provided to compression circuitry 236. Otherwise, the input cleartext data is provided to the stored block generator 238.

Embodiments described herein can allow for a reduction (e.g., about 10%) of memory needed to store firmware, at least because the implementation of embodiments is done completely in hardware. Any determinations or logic needed to perform size comparisons and reading of bits is done solely in hardware, without the need for executing firmware. Hardware circuitry can provide support for any number of other compression algorithms with little or no additional hardware components or cost.

Hardware-based embodiments described herein can help improve throughput because no interaction with firmware is required. Uncompressed data blocks can be generated with hardware only, and little or no firmware interaction, increasing speed and throughput of example systems. Similarly, hardware accelerators can be locked for a lesser amount of time when using the hardware-based solutions described herein, increasing accelerator performance and overall system performance. Finally, an optimum or nearest-to-optimum compression ratio can be provided to users and external systems, based on configuration settings provided by users, applications, external systems, or other computing engines.

### Method for Creating and Using Uncompressed Data Blocks

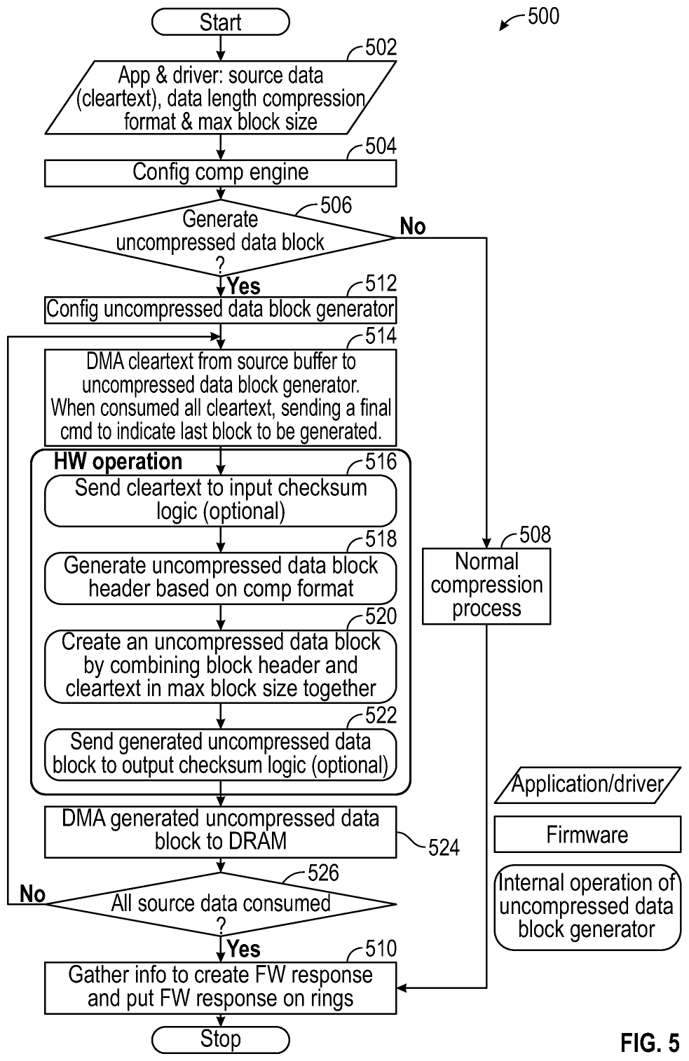

FIG. 5 illustrates a method 500 for generated uncompressed data blocks in accordance with some embodiments. Elements of the method 500 can be performed by any components of FIG. 2 and FIG. 3 and accordingly components of those figured are referred to in the below description.

Still referring to FIG. 5, input data 502 can include source data (e.g., cleartext) and parameters or indicators of data length, compression format, and maximum block size (see, e.g., parameters 304). The method 500 can begin at operation 504 by configuring compression engine/s. Configuration can be performed by determining the compression algorithm to be used (e.g., DEFLATE, LZ4, ZSTD, etc.). Other parameters can include compression level, window size, LZ4 MBS, etc. The method 500 can continue with decision 506 with determining whether to generate an uncompressed data block based on entropy criteria as described at threshold 232 and decision 234 (FIG. 2). If the determination is made not to generate an uncompressed data block, in operation 508 compression will occur using any of the algorithms described above. In operation 510, information is gathered to create a firmware response and put the firmware response on rings in the transport layer.

Otherwise, if the determination is made to generate uncompressed data blocks, the store block engine is configured at operation 512 according to, for example, the parameters described in input 304 (FIG. 3) such as MBS, compression algorithm, etc. and in operation 514, cleartext (e.g., input data 202) is DMA'd at DMA circuitry 204 (FIG. 2). Hardware circuitry 238 can optionally, in operation 516, provide cleartext to an input checksum. In operation 518, the hardware circuitry 238 can generate headers (as described above with respect to FIG. 3 and FIG. 4A-4C) for data blocks of the cleartext. In operation 520, the hardware circuitry 238 provides uncompressed data blocks (which include headers and cleartext blocks as described earlier herein). Optionally, at operation 522, the uncompressed data blocks are provided for CRC functions (e.g., operation 314).

In operation 524 (similarly to blocks 208 (FIG. 2)), the generated uncompressed data blocks are DMA'd to RAM. In some examples, according to criteria and algorithms described above, compressed data can be provided. Operations can resume based on decision 526 until all input cleartext or other data has been handled.

### Other Components

Referring again to FIG. 1, other components of the system are described. The processor(s) 106 may include one or more single-core processors, multi-core processors, digital signal processors (DSPs), microcontrollers, or other processor(s) or processing/controlling circuit(s). In some embodiments, the processor(s) 106 can include an FPGA, an ASIC, reconfigurable hardware or hardware circuitry, or other specialized hardware to facilitate performance of the functions described herein.

The memory 108 may be embodied as any type of volatile or non-volatile memory or data storage capable of performing the functions described herein. It should be appreciated that the memory 108 may include main memory (e.g., a primary memory) and/or cache memory (e.g., memory that can be accessed more quickly than the main memory). Volatile memory may be a storage medium that requires power to maintain the state of data stored by the medium. Non-limiting examples of volatile memory may include various types of random access memory (RAM), such as dynamic random access memory (DRAM) or static random access memory (SRAM).

The compute engine 104 is communicatively coupled to other components of the compute device 102 via the I/O subsystem 110, which may be embodied as circuitry and/or components to facilitate input/output operations with the processor 106, the memory 108, and other components of the compute device 102. For example, the I/O subsystem 110 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some embodiments, the I/O subsystem 110 may form a portion of a SoC and be incorporated, along with one or more of the processor(s) 106, the memory 108, and other components of the compute device 102, on a single integrated circuit chip.

The one or more data storage devices 112 can include any type of storage device(s) configured for short-term or long-term storage of data, such as, for example, memory devices and circuits, memory cards, hard disk drives, solid-state drives, or other data storage devices. Each data storage device 112 may include a system partition that stores data and firmware code for the data storage device 112. Additionally, or alternatively, each data storage device 112 may also include an operating system partition that stores data files and executables for an operating system.

The communication circuitry 114 may include any communication circuit, device, or collection thereof, capable of enabling communications between the compute device 102 and other computing devices, as well as any network communication enabling devices, such as an access point, network switch/router, etc., to allow communication over a communicatively coupled network. Accordingly, the communication circuitry 114 may be configured to use any one or more communication technologies (e.g., wireless or wired communication technologies) and associated protocols (e.g., Ethernet, Bluetooth®, WiMAX, LTE, 5G, etc.) to affect such communication.

The communication circuitry 114 may include specialized circuitry, hardware, or combination thereof to perform pipeline logic (e.g., hardware algorithms) for performing the functions described herein, including processing network packets (e.g., parse received network packets, determine destination computing devices for each received network packets, forward the network packets to a particular buffer queue of a respective host buffer of the compute device 102, etc.), performing computational functions, etc.

In some embodiments, performance of one or more of the functions of communication circuitry 114 as described herein may be performed by specialized circuitry, hardware, or combination thereof of the communication circuitry 114, which may be embodied as a SoC or otherwise form a portion of a SoC of the compute device 102 (e.g., incorporated on a single integrated circuit chip along with a processor 106, the memory 108, and/or other components of the compute device 102). Alternatively, in some embodiments, the specialized circuitry, hardware, or combination thereof may be embodied as one or more discrete processing units of the compute device 102, each of which may be capable of performing one or more of the functions described herein.

The one or more peripheral devices 116 may include any type of device that is usable to input information into the compute device 102 and/or receive information from the compute device 102. The peripheral devices 116 may be embodied as any auxiliary device usable to input information into the compute device 102, such as a keyboard, a mouse, a microphone, a barcode reader, an image scanner, etc., or output information from the compute device 102, such as a display, a speaker, graphics circuitry, a printer, a projector, etc. It should be appreciated that, in some embodiments, one or more of the peripheral devices 116 may function as both an input device and an output device (e.g., a touchscreen display, a digitizer on top of a display screen, etc.). It should be further appreciated that the types of peripheral devices 116 connected to the compute device 102 may depend on, for example, the type and/or intended use of the compute device 102. Additionally, or alternatively, in some embodiments, the peripheral devices 116 may include one or more ports, such as a USB port, for example, for connecting external peripheral devices to the compute device 102.

### Examples and Notes

Example 1 is an accelerator apparatus, an input interface to receive input data to be compressed and user application parameters for invocation of compression; and circuitry coupled to the input interface and configured to: identify a compression algorithm from configuration data provided with the input data, wherein the user application parameters do not include parameters specifying entropy thresholds for compression of the input data; generate headers specific to the compression algorithm; generate uncompressed data blocks comprising blocks of the input data and corresponding headers; and determine whether to provide the uncompressed data blocks or compressed data blocks based at least in part on entropy of the input data.
In Example 2, the subject matter of Example 1 can optionally include wherein the configuration data is specified by a user application providing the input data.
In Example 3, the subject matter of any of Examples 1-2 can optionally include wherein the compression algorithm is identified using a hardware switch circuitry, the hardware switch circuitry configured to select circuitry for generating corresponding headers based on the identified compression algorithm.
In Example 4, the subject matter of any of Examples 1-3 can optionally include wherein an indicator of the compression algorithm is provided as an input parameter to the accelerator apparatus.
In Example 5, the subject matter of any of Examples 1-4 can optionally include a buffer to receive, through direct memory access, cleartext representation of the input data.
In Example 6, the subject matter of any of Examples 1-5 can optionally include a buffer to store uncompressed data blocks for output.
In Example 7, the subject matter of any of Examples 1-6 can optionally include checksum circuitry.
In Example 8, the subject matter of any of Examples 1-7 can optionally include wherein the accelerator apparatus is a component of a cryptographic accelerator.
In Example 9, the subject matter of any of Examples 1-8 can optionally include wherein the accelerator apparatus is standalone on a die.
In Example 10, the subject matter of any of Examples 1-9 can optionally include wherein the accelerator apparatus is incorporated in a system on chip (SoC).
In Example 11, the subject matter of any of Examples 1-10 can optionally include wherein the accelerator apparatus is incorporated in a field programmable gate array (FPGA).
Example 12 is a computing device comprising: communication circuitry; and an accelerator apparatus coupled to the communication circuitry and configured to: receive, from the communication circuitry, input data to be compressed and user application parameters for invocation of compression; identify a compression algorithm from configuration data provided with the input data, wherein the user application parameters do not include parameters specifying entropy thresholds for compression of the input data; generate headers specific to the compression algorithm; generate uncompressed data blocks comprising blocks of the input data and corresponding headers; and determine whether to output the uncompressed data blocks or compressed data blocks to the communication circuitry based at least in part on an entropy identified by the configuration data.
In Example 13, the subject matter of Example 12 can optionally include wherein the configuration data is specified by a user application providing the input data.
In Example 14, the subject matter of any of Examples 12-13 can optionally include wherein the accelerator apparatus further comprises hardware switch circuitry configured to identify the compression algorithm and to select circuitry for generating corresponding headers based on the identified compression algorithm.
In Example 15, the subject matter of any of Examples 12-14 can optionally include memory to receive, through direct memory access, cleartext representation of the input data.
Example 16 is a method comprising: receiving input data to be compressed and user application parameters for invocation of compression; identifying a compression algorithm from configuration data provided with the input data wherein the user application parameters do not include parameters specifying entropy thresholds for compression of the input data; generating headers specific to the compression algorithm; generating uncompressed data blocks comprising blocks of the input data and corresponding headers; and determining whether to provide the uncompressed data blocks or compressed data blocks based on an entropy identified by the configuration data.
In Example 17, the subject matter of Example 16 can optionally include wherein the configuration data is specified by a user application providing the input data.
In Example 18, the subject matter of any of Examples 16-17 can optionally include receiving, through direct memory access, cleartext representation of the input data.
Example 19 is a machine-readable medium including instructions that, when executed on a processor, cause the processor to perform functions including: generating an application programming interface (API) call to compression accelerator circuitry, the API call including data to be compressed by the accelerator circuitry and the API call not including parameters specifying entropy thresholds for compression of the input data; and receiving output data including header information indicating whether the output data includes compressed data.
In Example 20 the subject matter of Example 19 can optionally include wherein the header includes information indicating a compression algorithm used for compressing the data.

Examples, as described herein, may include, or may operate on, logic or a number of components, modules, or mechanisms. Modules may be hardware, software, or firmware communicatively coupled to one or more processors to carry out the operations described herein. Modules may be hardware modules, and as such modules may be considered tangible entities capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations. The operations can include generating an API call to compression accelerator circuitry as described earlier herein. The API call can include data to be compressed by the accelerator circuitry. As described above, because determination of compression algorithms to be used and determination of entropy of the input data to be compressed is performed within hardware circuitry of the accelerator circuitry, the API call may not include parameters specifying entropy thresholds for compression of the input data. Accordingly, the term hardware module is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software; the general-purpose hardware processor may be configured as respective different modules at different times. Software may accordingly configure a hardware processor, for example, to constitute a particular module at one instance of time and to constitute a different module at a different instance of time. Modules may also be software or firmware modules, which operate to perform the methodologies described herein.

Circuitry or circuits, as used in this document, may comprise, for example, singly or in any combination, hardwired circuitry, programmable circuitry such as computer processors comprising one or more individual instruction processing cores, state machine circuitry, and/or firmware that stores instructions executed by programmable circuitry. The circuits, circuitry, or modules may, collectively or individually, be embodied as circuitry that forms part of a larger system, for example, an integrated circuit (IC), system on-chip (SoC), desktop computers, laptop computers, tablet computers, servers, smart phones, etc.

As used in any embodiment herein, the term “logic” may refer to firmware and/or circuitry configured to perform any of the aforementioned operations. Firmware may be embodied as code, instructions or instruction sets and/or data that are hard-coded (e.g., nonvolatile) in memory devices and/or circuitry.

“Circuitry,” as used in any embodiment herein, may comprise, for example, singly or in any combination, hardwired circuitry, programmable circuitry, state machine circuitry, logic and/or firmware that stores instructions executed by programmable circuitry. The circuitry may be embodied as an integrated circuit, such as an integrated circuit chip. In some embodiments, the circuitry may be formed, at least in part, by the processor circuitry executing code and/or instructions sets (e.g., software, firmware, etc.) corresponding to the functionality described herein, thus transforming a general-purpose processor into a specific-purpose processing environment to perform one or more of the operations described herein. In some embodiments, the processor circuitry may be embodied as a stand-alone integrated circuit or may be incorporated as one of several components on an integrated circuit. In some embodiments, the various components and circuitry of the node or other systems may be combined in a system-on-a-chip (SoC) architecture.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

What is claimed is:

1. An accelerator apparatus, comprising:
an input interface to receive input data to be compressed and user application parameters for invocation of compression; and
circuitry coupled to the input interface and configured to:
identify a compression algorithm from configuration data provided with the input data, wherein the user application parameters do not include parameters specifying entropy thresholds for compression of the input data;
generate headers specific to the compression algorithm;
generate uncompressed data blocks comprising blocks of the input data and corresponding headers; and
determine whether to provide the uncompressed data blocks or compressed data blocks based at least in part on entropy of the input data.

2. The accelerator apparatus of claim 1, wherein the configuration data is specified by a user application providing the input data.

3. The accelerator apparatus of claim 1, wherein the compression algorithm is identified using a hardware switch circuitry, the hardware switch circuitry configured to select circuitry for generating corresponding headers based on the identified compression algorithm.

4. The accelerator apparatus of claim 1, wherein an indicator of the compression algorithm is provided as an input parameter to the accelerator apparatus.

5. The accelerator apparatus of claim 1, further comprising:
a buffer to receive, through direct memory access, cleartext representation of the input data.

6. The accelerator apparatus of claim 1, further comprising:
a buffer to store uncompressed data blocks for output.

7. The accelerator apparatus of claim 1, further comprising checksum circuitry.

8. The accelerator apparatus of claim 1, wherein the accelerator apparatus is a component of a cryptographic accelerator.

9. The accelerator apparatus of claim 1, wherein the accelerator apparatus is standalone on a die.

10. The accelerator apparatus of claim 1, wherein the accelerator apparatus is incorporated in a system on chip (SoC).

11. The accelerator apparatus of claim 1, wherein the accelerator apparatus is incorporated in a field programmable gate array (FPGA).

12. A computing device comprising:
communication circuitry; and
an accelerator apparatus coupled to the communication circuitry and configured to:
receive, from the communication circuitry, input data to be compressed and user application parameters for invocation of compression;
identify a compression algorithm from configuration data provided with the input data, wherein the user application parameters do not include parameters specifying entropy thresholds for compression of the input data;
generate headers specific to the compression algorithm;
generate uncompressed data blocks comprising blocks of the input data and corresponding headers; and
determine whether to output the uncompressed data blocks or compressed data blocks to the communication circuitry based at least in part on an entropy identified by the configuration data.

13. The computing device of claim 12, wherein the configuration data is specified by a user application providing the input data.

14. The computing device of claim 12, wherein the accelerator apparatus further comprises hardware switch circuitry configured to identify the compression algorithm and to select circuitry for generating corresponding headers based on the identified compression algorithm.

15. The computing device of claim 12, further comprising memory to receive, through direct memory access, cleartext representation of the input data.

16. A machine-readable medium including instructions that, when executed on a processor, cause the processor to perform functions including:
generating an application programming interface (API) call to compression accelerator circuitry, the API call including data to be compressed by the accelerator circuitry and the API call not including parameters specifying entropy thresholds for compression of the data to be compressed; and
receiving output data including header information indicating whether the output data includes compressed data.

17. The machine-readable medium of claim 16, wherein the header includes information indicating a compression algorithm used for compressing the data.

18. The machine-readable medium of claim 17, wherein the header indicates that the compression algorithm comprises a DEFLATE compression algorithm.
